(19) United States
(12) Patent Application Publication
(10) Pub. No.: US 2006/0199352 A1
(43) Pub. Date: Sep. 7, 2006

(54) Method of manufacturing shallow trench isolation structure

(76) Inventors: Min-San Huang, Hsinchu (TW); Pin-Yao Wang, Hsinchu City (TW); Jeng-Huan Yang, Hsinchu City (TW)

Correspondence Address: J C PATENTS, INC., 4 VENTURE, SUITE 250, IRVINE, CA, 92618, US

(21) Appl. No.: 11/154,380

(22) Filed: Jun. 15, 2005

(30) Foreign Application Priority Data
Mar. 3, 2005 (TW) 94106402

(51) Int. Cl. H01L 21/76

(52) U.S. Cl. 438/424

(57) ABSTRACT

A method of manufacturing a shallow trench isolation structure adapted for a substrate, is provided. A dielectric film is formed on the substrate and then a buffer layer having a first thickness is formed on the dielectric film. Then, a hard mask layer having a second thickness is formed on the buffer layer. The hard mask layer, the buffer layer, the dielectric film and the substrate are patterned to form an opening in the hard mask layer, the buffer layer and the dielectric film and a trench in the substrate. An insulating layer is formed to fill up the opening and the trench. Thereafter, the hard mask layer, a portion of the insulating layer and the buffer layer are removed to form a shallow trench isolation structure that protrudes out of the substrate surface.

### BACKGROUND OF THE INVENTION

1. Field of the Invention

The present invention relates to a method of manufacturing the isolation structure of integrated circuit devices. More particularly, the present invention relates to a method of manufacturing a shallow trench isolation (STI) structure.

2. Description of the Related Art

With the rapid development in integrated circuits technology, device miniaturization and integration is the ultimate goal for many integrated circuit manufacturers. As the device dimensions continue to shrink and the level of integration increases, device isolation structures for separating the devices must be minimized correspondingly. As a result, the technique of isolating the devices becomes more complicated. In the past, one method of isolating a device structure was to perform a local oxidation of silicon (LOCOS) process to form a field oxide layer on a substrate. However, limited by the “Bird's Beak” shape, the field oxide layer cannot be further minimized. Thus, other types of device isolation techniques, such as the shallow trench isolation (STI) process, have been developed and widely adopted, especially in the sub-half micron process for forming integrated circuits.

FIG. 1 is a schematic cross-sectional view of a shallow trench isolation structure formed using a conventional method. In the conventional method of manufacturing a shallow trench isolation structure, a silicon nitride (not shown) is generally used as a hard mask in an anisotropic etching process for forming a steep trench on a semiconductor substrate. Thereafter, silicon oxide is deposited to fill the trench and serve as a shallow trench isolation structure 112 for the devices. However, in the conventional manufacturing method, because of the etching characteristics of silicon nitride material, the sidewalls of the silicon nitride are easily etched to form a trench having an inverted trapezium cross section. After filling the trench with the silicon oxide material 112, the sidewalls 114 of the silicon oxide layer 112 and the surface of the substrate 100 (the circled area 120 in FIG. 1) could form a corner with an acute angle. As the integration level of the device is increased or the thickness of the shallow trench isolation is increased (for example, in the manufacturing of trench type flash memory), the acute-angle corner becomes smaller. In a subsequent fabrication process, for example, when forming the source and the drain through an ion implantation process, the substrate underneath this acute-angle region can accumulate electric charges and lead to the flow of an abnormal sub-threshold current in the transistor channel. Ultimately, a kink effect would occur in which the transistor can hardly operate normally or polysilicon stringers are produced.

### SUMMARY OF THE INVENTION

Accordingly, at least one objective of the present invention is to provide a method for manufacturing a shallow trench isolation structure capable of forming a shallow trench isolation structure having a sidewall perpendicular to the substrate surface. Hence, the acute-angle corner between the sidewall of a conventional shallow trench isolation structure and the substrate surface is removed so that the issues of polysilicon stringers and abnormal electrical performance are resolved.

To achieve these and other advantages and in accordance with the purpose of the invention, as embodied and broadly described herein, the invention s provides a method of manufacturing a shallow trench isolation (STI) structure on a substrate. First, a substrate is provided and then a dielectric film is formed on the substrate. Then, a buffer layer having a first thickness is formed on the dielectric film, and a hard mask layer having a second thickness is formed on the buffer layer. The hard mask layer, the buffer layer, the dielectric film and the substrate are patterned to form an opening in the hard mask layer, the buffer layer and the dielectric film, and a trench in the substrate. An insulating layer is formed to fill the opening and the trench. Thereafter, the hard mask layer, a portion of the insulating layer and the buffer layer are removed to form a shallow trench isolation structure protruding above the substrate surface.

According to the method of manufacturing shallow trench isolation structure in the embodiment of the present invention, the first thickness is between about 750 Å˜950 Å, and the second thickness is between about 750 Å˜950 Å. The method of removing the hard mask layer, a portion of the insulating layer and the buffer layer includes removing the hard mask layer to expose the buffer layer, removing a portion of the insulating layer using the buffer layer as a stop layer, and removing the buffer layer. Furthermore, the method of removing a portion of the insulating layer includes performing a dry etching process. The hard mask layer can be a silicon nitride layer, and the buffer layer can be a polysilicon layer. The method of patterning the hard mask layer, the buffer layer, the dielectric film and the substrate to form a trench in the substrate includes patterning the hard mask layer, the buffer layer and the dielectric film to form an opening in the hard mask layer, the buffer layer and the dielectric film and then removing a portion of the substrate to form a trench using the hard mask layer, the buffer layer and the dielectric film as a mask. The method of patterning the hard mask layer, the buffer layer and the dielectric film includes performing an anisotropic etching process.

The present invention also provides an alternative method of manufacturing a shallow trench isolation structure. First, a dielectric film, a polysilicon layer and a hard mask layer are sequentially formed over a substrate. The polysilicon layer has a thickness between about 750 Å˜950 Å. The hard mask layer, the polysilicon layer, and the dielectric film are patterned to form an opening in the hard mask layer, the polysilicon layer and the dielectric film. The polysilicon layer exposed by the opening has a sidewall perpendicular to the substrate. Using the hard mask layer, the polysilicon layer and the dielectric film as a mask, a portion of the substrate is removed to form a trench in the substrate. An insulating material is deposited over the substrate to form an insulating material layer. The insulating layer outside the opening is removed to form an insulating layer that completely fills the opening and the trench. The hard mask layer, a portion of the insulating layer and the buffer layer are removed to form a shallow trench isolation structure that protrudes above the surface of the substrate. The portion of the shallow trench isolation structure protruding above the surface of the substrate has a sidewall perpendicular to the substrate.

According to the method of manufacturing shallow trench isolation structure in the embodiment of the present invention, the hard mask layer has a thickness between about 750 Å˜950 Å. The method of removing a portion of the insulating material layer includes performing a chemical-mechanical polishing process. The hard mask layer can be a silicon nitride layer. The method of patterning the hard mask layer, the polysilicon layer and the dielectric film includes performing an anisotropic etching process.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a shallow trench isolation structure formed using a conventional method.

FIGS. 2A through 2E are schematic cross-sectional views showing the method of manufacturing a shallow trench isolation structure according to the present invention.

FIGS. 3A and 3B are schematic cross-sectional views showing an alternative method of manufacturing a shallow trench isolation structure according the present invention.

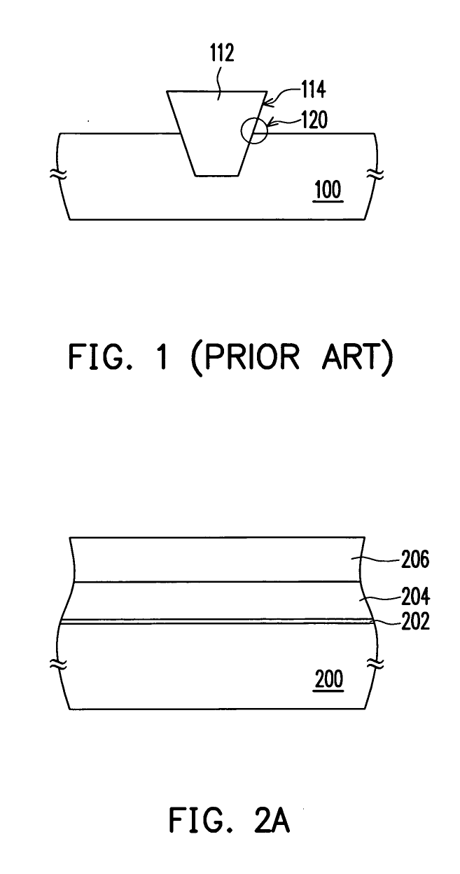

### DESCRIPTION OF THE EMBODIMENTS

Reference is now made in detail to the present embodiments of the invention, examples of which are illustrated in the accompanying drawings. Wherever possible, the same reference numbers are used in the drawings and the description to refer to the same or like parts.

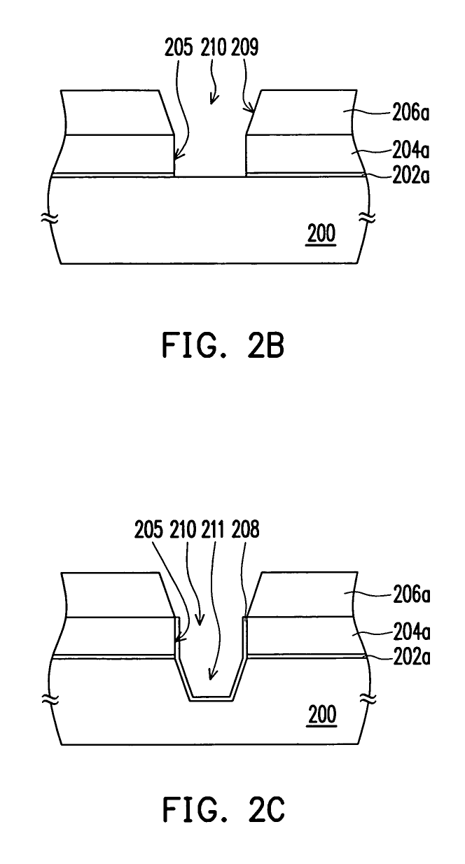

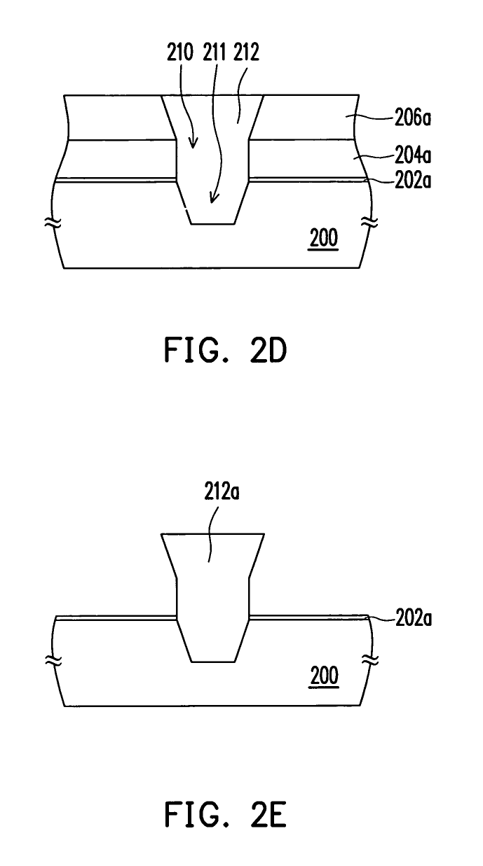

FIGS. 2A through 2E are schematic cross-sectional views showing the method of manufacturing a shallow trench isolation structure according to the present invention. First, as shown in FIG. 2A, a substrate 200 is provided. The substrate 200 has a dielectric film 202, a buffer layer 204 and a hard mask layer 206 sequentially formed thereon. The dielectric film 202 is fabricated using silicon oxide, for example. The buffer layer 204 is fabricated using a material capable of forming a vertical sidewall in a subsequent etching process and having an etching selectivity different from that of a subsequently-formed insulating layer. The buffer layer 204 is a polysilicon layer formed, for example, by performing a chemical vapor deposition process. In addition, the buffer layer 204 has a thickness between about 750 Å˜950 Å. The hard mask layer 206 is a silicon nitride layer formed, for example, by performing a chemical vapor deposition process. The hard mask layer 206 has a thickness between about 750 Å˜950 Å.

As shown in FIG. 2B, the hard mask layer 206, the buffer layer 204 and the dielectric film 202 are patterned to form a hard mask layer 206a, a buffer layer 204a and a dielectric film 202a having an opening 210 therein. The opening 210 exposes a portion of the surface of the substrate 200. The method of patterning the hard mask layer 206, the buffer layer 204 and the dielectric film 202 includes performing a photolithographic process and an etching process in sequence. The etching process is an anisotropic etching operation, for example. The buffer layer 204a is fabricated from a material capable of forming a vertical sidewall after the etching process. Although a portion of the sidewall 209 of the opening 210 formed in the hard mask layer 206 is not strictly perpendicular to the surface of the substrate 200 when the hard mask layer 206a is fabricated from silicon nitride, a portion of the sidewall 205 of the opening 210 formed in the buffer layer 204a is perpendicular to the surface of the substrate 200.

As shown in FIG. 2C, using the hard mask layer 206a and the buffer layer 204a as a mask, an etching process is performed to remove a portion of the substrate 200 and form a trench 211 in the substrate 200. Thereafter, an oxidation process is performed to form a liner oxide layer 208 on the bottom and sidewalls of the trench as well as the portion of the sidewalls 205 of the opening 210 formed in the buffer layer 204a. The method of forming the liner oxide layer 208 includes performing a thermal oxidation process. Hence, a liner oxide layer having a thickness between about 50 Å to 200 Å is formed on the exposed substrate 200 within the trench 211 and the exposed sidewall 205 of the buffer layer 204a within the opening 210.

As shown in FIG. 2D, an insulating layer 212 that completely fills the trench 211 and the opening 210 is formed over the substrate 200. The method of forming the insulating layer 212 includes depositing insulating material to a thickness of between 4000 Å to 10000 Å over the hard mask layer 206a so that the insulating material completely fills the trench 211 and the opening 210. The insulating material layer (not shown) is commonly fabricated using silicon oxide and formed by performing an atmospheric pressure chemical vapor deposition (APCVD) process, for example. Thereafter, a densification process is performed at a temperature of about 1000° C. for about 10 to 30 minutes to produce a finer insulating layer structure. It should be noted that the actual thickness of the insulating layer 212 ought to match the actual thickness of the trench 211 and other deposition layers. After the densification step, a chemical-mechanical polishing (CMP) or a back etching process is performed using the hard mask layer 206a as a stop layer to remove a portion of the insulating material layer over the hard mask layer 206a. Thus, the insulating layer 212 within the trench 211 and the opening 210 is retained.

As shown in FIG. 2E, using the hard mask layer 206a as a stop layer, a portion of the insulating material layer is removed. Thereafter, the mask layer 206a and the buffer layer 204a are directly removed to form a shallow trench isolation structure 212a (the insulating layer 212 in FIG. 2D). As a result of the aforementioned steps, the height of the shallow trench isolation structure 212a above the surface of the substrate 200 can be determined by the thickness of the aforementioned mask layer 206 and buffer layer 204.

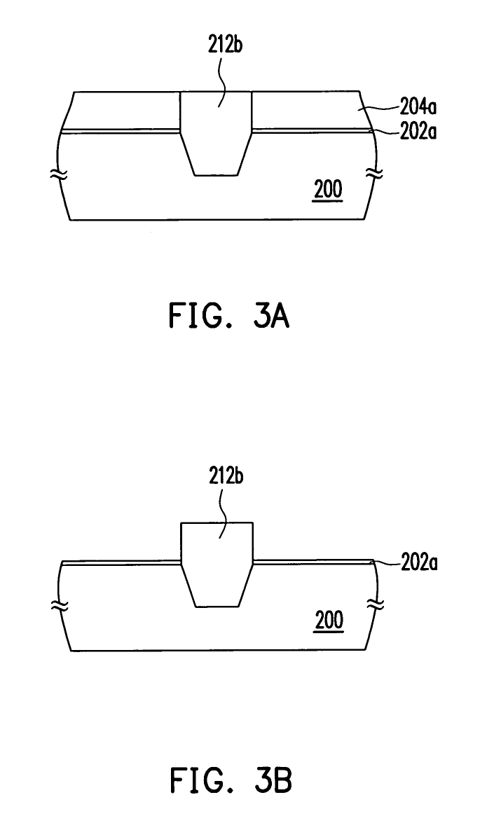

On the other hand, after removing a portion of the material layer using the hard mask layer 206a as a stop layer, the hard mask layer 206a and a portion of the insulating layer 212 can be sequentially removed to form a shallow trench isolation structure 212b as shown in FIG. 3A. The method of forming the shallow trench isolation structure 212b includes performing a chemical-mechanical polishing process or a dry etching process using the buffer layer 204a as a stop layer.

Thereafter, as shown in FIG. 3B, the buffer layer 204a is removed to complete the process of fabricating the shallow trench isolation structure 212b. In the present embodiment, the height of the shallow trench isolation structure 212b protruding above the surface of the substrate 200 can be determined according to the thickness of the aforementioned buffer layer 204.

Because a portion of the shallow trench isolation structure 212 is removed using the buffer layer 204a as a stop layer, the tapering portion of the shallow trench isolation structure in the opening surrounded by the patterned hard mask layer 206a can be removed. After the buffer layer 204a is removed, the portion of the shallow trench isolation structure 212b protruding above the surface of the substrate 200 has a sidewall perpendicular to the substrate.

With respect to the height of about 200 Å above the surface of the substrate for a conventionally fabricated shallow trench isolation structure, the shallow trench isolation structure fabricated according to the present invention has a protruding height of about 750 Å˜950 Å above the substrate surface. Furthermore, the height of the shallow trench isolation structure protruding above the surface of the substrate can be determined by the thickness of the buffer layer or the mask layer. Using the etching properties of the buffer layer, a buffer layer having a sidewall perpendicular to the substrate surface can be formed. Hence, by using a buffer layer having a thickness equal to the thickness of the hard mask layer, the perpendicularity of the sidewall of the subsequently formed shallow trench isolation structure to the substrate surface can be increased. In other words, the buffer layer has the capacity to straighten the shallow trench isolation structure. Therefore, the issues of polysilicon stringers and abnormal electrical performance are resolved by forming the tapering shallow trench isolation structure for increasing the height of the shallow trench isolation structure above the substrate surface in the conventional method. Furthermore, the method for forming the shallow trench isolation structure according to the present invention is also suitable for the manufacturing process of trench type semiconductor devices (for example, trench type flash memory) for forming the device isolation structure in the in a subsequent process.

It is apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for manufacturing a shallow trench isolation structure, comprising:
providing a substrate;
forming a dielectric film on the substrate;
forming a buffer layer over the dielectric film;
forming a hard mask layer on the buffer layer, wherein the hard mask layer, the buffer layer and the substrate all have different etching properties;
removing a portion of the hard mask layer, the buffer layer, the dielectric film and the substrate to form an opening in the hard mask layer, the buffer layer and the dielectric film, and then forming a trench in the substrate;
forming an insulating layer that fills the opening and the trench; and
removing the residual hard mask layer and the residual buffer layer so as to form a shallow trench isolation structure in the substrate which protrudes out of the surface of the substrate, wherein the buffer layer has a property of straightening up the shallow trench isolation structure.

2. The method of manufacturing the shallow trench isolation structure of claim 1, wherein before removing the residual buffer layer, the method further comprises:
removing the residual hard mask layer to expose the surface of the buffer layer; and
removing a portion of the insulating layer using the buffer layer as a stop layer.

3. The method of manufacturing the shallow trench isolation structure of claim 2, wherein the step of removing a portion of the insulating layer comprises performing a chemical-mechanical polishing process.

4. The method of manufacturing the shallow trench isolation structure of claim 1, wherein the material constituting the hard mask layer comprises silicon nitride.

5. The method of manufacturing the shallow trench isolation structure of claim 4, wherein the hard mask layer has a thickness between about 750 Å˜950 Å.

6. The method of manufacturing the shallow trench isolation structure of claim 1, wherein the material constituting the buffer layer comprises polysilicon.

7. The method of manufacturing the shallow trench isolation structure of claim 6, wherein the buffer layer has a thickness between about 750 Å˜950 Å.

8. The method of manufacturing the shallow trench isolation structure of claim 1, wherein the step of forming a trench in the substrate comprises:
patterning the hard mask layer, the buffer layer and the dielectric film to form the opening in the hard mask layer, the buffer layer and the dielectric film; and
removing a portion of the substrate to form the trench using the residual hard mask layer, the residual buffer layer and the residual dielectric film as a mask.

9. The method of manufacturing the shallow trench isolation structure of claim 8, wherein the step of patterning the hard mask layer, the buffer layer and the dielectric film comprises performing an anisotropic etching process.

10. A method of manufacturing a shallow trench isolation structure, comprising
providing a substrate;
forming a dielectric film, a polysilicon layer and a hard mask layer sequentially on the substrate;
patterning the hard mask layer, the polysilicon layer and the dielectric film to form an opening in the hard mask layer, the buffer layer and the dielectric film, wherein the polysilicon layer exposed in the opening has a sidewall perpendicular to the substrate;
removing a portion of the substrate to form a trench using the hard mask layer, the polysilicon layer and the dielectric film as a mask;
forming an insulating material layer on the substrate;
removing the insulating material layer outside the opening to form an insulating layer that completely fills the opening and the trench; and
removing the hard mask layer, a portion of the insulating layer and the buffer layer to form a shallow trench isolation structure in the substrate such that a sidewall portion of the shallow trench isolation structure that protrudes out of the surface of the substrate is perpendicular to the substrate.

11. The method of manufacturing the shallow trench isolation structure of claim 10, wherein the polysilicon layer has a thickness between about 750 Å˜950 Å.

12. The method of manufacturing the shallow trench isolation structure of claim 10, wherein the material constituting the hard mask layer comprises silicon nitride.

13. The method of manufacturing the shallow trench isolation structure of claim 12, wherein the hard mask layer has a thickness between about 750 Å˜950 Å.

14. The method of manufacturing the shallow trench isolation structure of claim 10, wherein the step of removing a portion of the insulating material layer comprises performing a chemical-mechanical polishing process.

15. The method of manufacturing the shallow trench isolation structure of claim 10, wherein the step of patterning the hard mask layer, the buffer layer and the dielectric film comprises performing an anisotropic etching process.
